(19) United States
(12) Patent Application Publication
(10) Pub. No.: US 2003/0043675 A1
(43) Pub. Date: Mar. 6, 2003

(54) Memory system

(76) Inventors: Eric Cordes, Munchen (DE); Georg Erhard Eggers, Munchen (DE)

Correspondence Address: LERNER AND GREENBERG, P.A., Post Office Box 2480, Hollywood, FL, 33022-2480, US

(21) Appl. No.: 10/236,887

(22) Filed: Sep. 6, 2002

(30) Foreign Application Priority Data
Sep. 6, 2001 (DE) 101 43 766.8

(51) Int. Cl. G11C 7/00

(52) U.S. Cl. 365/222; 365/233

(57) ABSTRACT

A memory system comprising at least one memory cell in which information can be stored and a refreshing means refreshing the memory cell in predetermined time intervals is provided. In addition, the memory cell comprises a driving means driving the refreshing means in such a way that it only refreshes the memory cell when useful information is stored in the memory cell.

### BACKGROUND OF THE INVENTION

1. Field of the Invention

The present invention relates to the field of memory systems and, in particular, to the field of memory systems having dynamic memories.

2. Description of the Related Art

Memories in which a physical quantity, such as, for example, electrical charges, must be refreshed in time intervals in order not to lose useful information stored in the memory are referred to as dynamic memories. In computer systems, for example, DRAM memories (DRAM=dynamic random access memory) having a plurality of memory cells are used, a plurality of memory cells typically being connected to a common data line. Typical methods of refreshing such a plurality of memory cells are the cycle stealing method and the transparent method or hidden refresh method, respectively. In the cycle stealing method, the memory cells of a common data line, such as, for example, of a word line, are refreshed together, each word line being refreshed after the other. A counter which is incremented by 1 after each refresh process for a word line is used for this. During the refresh process of a word line, a processor connected to the memory system is thus paused for one clock cycle.

In the transparent method, the refreshing is performed in a synchronized way such that refreshing memory cells of a word line is only performed when a user does not access the memory cells of the word line.

With the increasing usage of portable computing devices, such as, for example, laptops, palm tops or organizers, the use of SDRAM memories (SDRAM=synchronous dynamic random access memory) is becoming more and more important on the market. In such applications, the power consumption is a decisive criterion due to the fact that these apparatuses are typically driven by a battery.

As is well-known, the memory cells are refreshed in fixed time intervals, no difference being made whether useful information is actually written to the memory cells or not. Thus, in well-known systems, for example after starting, when many memory cells do not have useful information, an unnecessary amount of power is consumed by refreshing memory cells having no useful information, which can represent an essential part of the overall power consumption.

### SUMMARY OF THE INVENTION

It is the object of the present invention to provide a concept to operate a memory system having memory cells which must be refreshed with a reduced power consumption.

The present invention is a memory system having at least one memory cell in which information can be stored, a refreshing means refreshing the memory cells in predetermined time intervals, and a driving means driving the refreshing means in such a way that it only refreshes the memory cell when useful information is stored in the memory cell.

The present invention is based on the recognition that, in a memory system including memory cells which must be refreshed again, a low power consumption is obtained by only refreshing memory cells containing useful information in the memory system.

In a preferred embodiment of the present invention, the memory system comprises a mono flop receiving a write signal at a set input in the write process to a memory cell, the signal indicating writing to the memory cell, whereby setting the mono flop is performed. An output of the mono flop is connected to an AND logic element further receiving a refresh signal at a second input. The output of the AND logic element is connected to an input of a control for triggering a refresh process. In the set state of the mono flop, at each reception of a refresh signal at the AND logic element, a signal for performing a refresh is output to a refreshing means via the output of the AND logic element, the signal causing the refreshing means to effect a refresh of the memory cell.

### BRIEF DESCRIPTION OF THE DRAWINGS

Preferred embodiments of the present invention will be detailed subsequently referring to the appended drawings, in which:

FIG. 1 shows a schematic block diagram of an embodiment of the present invention; and

FIG. 2 shows a schematic block diagram of a further embodiment showing an example of realizing the driving means.

### DESCRIPTION OF THE PREFERRED EMBODIMENTS

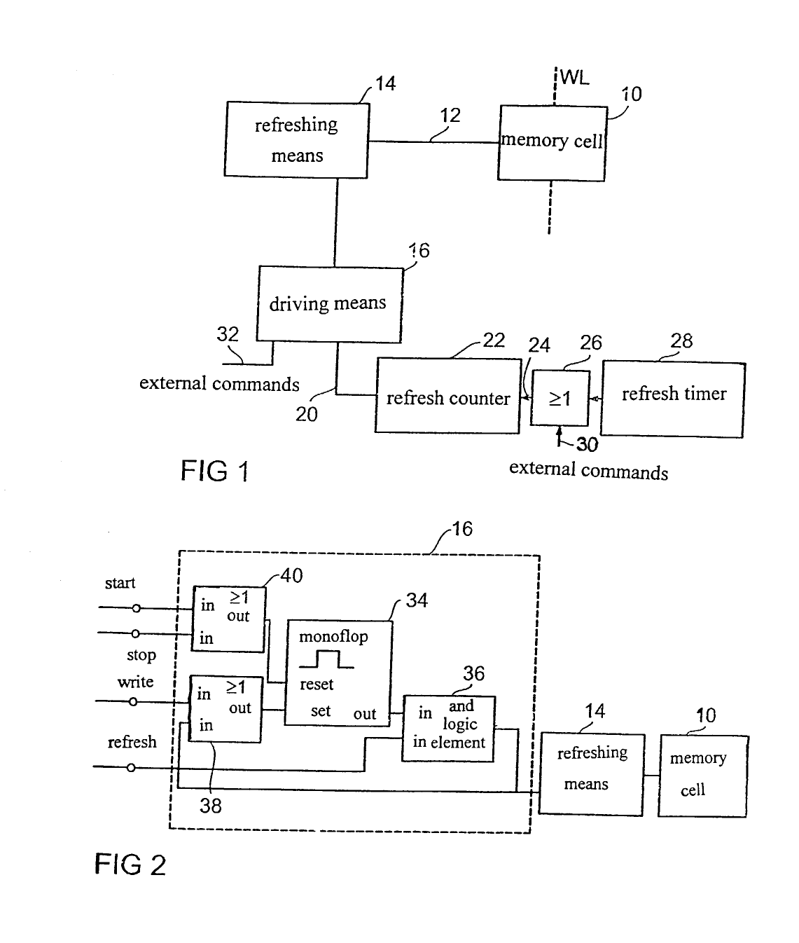

FIG. 1 is a block diagram showing a memory system according to an embodiment of the present invention. The memory system comprises a memory cell 10 connected to a refreshing means 14 via a refresh line 12. The memory cell 10 can, for example, include a DRAM memory cell or a SDRAM memory cell.

The memory system further comprises a driving means 16 connected to an input of the refreshing means 14 via a control line 18. In addition, the driving means 16 is connected to a refresh counter 22 via a control line 20. An output of the refresh counter is connected to an output of an OR logic element 26 via a line 24. A first input of the logic element 26 is connected to a refresh timer 28, while a second input of the logic element is connected to a line 30 for applying external commands.

According to an embodiment, the memory cell 10 is one of a plurality of memory cells provided in the memory system, several memory cells being connected by a common data line, such as, for example, a word line WL.

When powering up or starting, respectively, the memory system, i.e. when applying a supply voltage to the memory system, a power up signal or start signal, respectively, is applied to the driving means 16 via a line 32, the signal indicating that the memory system has been started. Since the memory cell 10 has no useful information after starting, the driving means 16 by receiving the start signal is set in such a state in which the driving means 16 controls the refreshing means 14 in such a way that no refresh of the memory cell 10 is performed by the refreshing means 14, although the driving means receives request signals for refreshing from the refresh counter 22 via the line 20.

The request signals are produced by the refresh counter 22 responsive to the reception of a trigger signal which is either a signal output by the refresh timer 28 or an external signal applied via the line 30.

If useful information is written to the memory cell 10 at a later time, the driving means 16, via the line 32, receives a write signal indicating that useful information has been written to the memory cell 10.

After receiving the write signal, the driving means 16 is in an active state in which responsive to receiving a request signal from the driving means 16, a signal to the refreshing means 14 is output, the signal causing the refreshing means 14 to perform a charge refresh of the memory cell 10. Performing a refresh of the memory cell 10 by the refreshing means 14 is performed in a well-known way.

The refresh counter receives a request signal from the refresh timer or via the external line 30 in regular time intervals so that refreshes of the memory cell 10 are performed in predetermined time intervals as long as the driving means is in the active state.

The active state of the driving means 16 is thus retained until the driving means 16 receives a cancel signal. The cancel signal is then applied to the driving means 16 via the line 32 when the information stored in the memory cell has no relevance for the usage, i.e. when it is no useful information which is, for example, used for operating a computer system connected to the memory system.

After the driving means 16 has received the cancel signal, the active state of the driving means 16 is stopped so that the memory cell 10 is not refreshed by the refreshing means 14, although the driving means 16 receives request signals for refreshing from the refresh counter 22 via the line 20.

The driving means 16 is thus set again in an active state when a signal is received via the line 32, indicating that useful information is stored in the memory cell 10. Such a signal can, for example, be the write signal mentioned above indicating writing useful information to the memory cell 10.

By the usage-oriented refresh of the memory cell 10, in which a refresh is only performed when relevant data information is stored in the memory cell 10, the power consumption caused by the memory system has a lower value than in well-known memory systems in which a recharging of a memory cell is performed in predetermined time intervals independently of the relevance of the information stored in the memory cell 10.

FIG. 2 shows an embodiment of the present invention, in which the driving means 16 of the memory system comprises a mono flop 34 having a reset input RESET, a set input SET and an output OUT. In addition, the memory system comprises an AND logic element having a first and a second input IN and an output OUT. The first input of the AND logic element is connected to the output of the mono flop 34. The second input of the AND logic element 36 receives a refresh signal via a refresh input REFRESH. The refresh signal corresponds to the signals for refreshing used in conventional systems, which are applied in predetermined intervals. Unlike in well-known systems, the refresh signal is not applied to the refreshing means but, according to the invention, to the AND logic element 36 to enable a selective refresh of a memory cell in this way.

The set input of the mono flop 34 is connected to an output of an OR logic element 38. A first input of the OR logic element 38 is connected to a write input WRITE, while a second input of the OR logic element 38 is connected to the output OUT of the AND logic element 36.

Further, the reset input RESET of the mono flop 34 is connected to an output of an OR logic element 40. The OR logic element 40 has a first and a second input IN, the first input being connected to a start input START, while the second input is connected to a logout input LOGOUT.

When starting the memory system, a start signal is applied to the reset input RESET of the mono flop 34 via the start input, the signal being applied to the reset input RESET of the mono flop 34 via the OR circuit element 40, whereby the mono flop 34 is reset in its stable state.

In this state the output of the mono flop 34 and consequently the first input of the AND logic element 36 are at a low level. In addition, a refresh signal having a high level is applied via the refresh input REFRESH of the driving means 16 and consequently at the second input of the AND logic element 36 in predetermined time intervals. The AND logic element 36 performs a combination of the levels applied to the first input and the second input.

If a low level is present at the first input of the AND logic element 36 by the reset state of the mono flop 34, the output of the AND logic element 36, independently of the occurrence of the refresh signal at the second input of the AND logic element 36, always has a low level. Since the output of the AND logic element 36 is connected to the refreshing means 14, it is notified by the low level that no refresh is performed.

This state continues until a write signal is applied to the set input of the mono flop 34 via the write input. By holding the mono flop 34, at the output OUT of it, at a high level for a hold time which is considerably longer than the information retention time of the memory cell 10, it is ensured that, with the next refresh signal, the mono flop 34 is not yet reset and that a high level is present at the first input of the AND logic element 36 so that, when the refresh signal occurs, the first and the second input of the AND logic element 36 have a high level, whereby the output of it is also set to a high level.

The high level applied thereto via the connection of the output of the AND logic element 36 and the input of the refreshing means 14 causes the refreshing means 14 to perform a refresh of the memory cell 10.

In addition, a high level is present at the set input of the mono flop 34 via the connection of it to the output of the AND logic element 36, whereby the mono flop 34 in turn is set and the measurement of the hold time is reset. As has already been mentioned, it is ensured by the long hold time of the mono flop 34, which is considerably longer than the information retention time of the memory cell 10, that the mono flop 34 has the set state in a subsequent refresh signal and that a refresh of the memory cell 10 is performed.

Consequently, a refresh of the memory cell 10 is performed for each further refresh signal until a signal is applied to the reset input of the mono flop 34 via the logout input, the signal indicating the memory contents of the memory cell 10 to be irrelevant and resetting the mono flop 34 to a low level.

If the refresh signal at the second input of the AND logic element 36 is disrupted or stopped, no refresh of the memory cell is performed, the mono flop 34 remaining set by the long hold time for a period of time which is considerably longer than the information retention time of the memory cell 10.

Thus the mono flop 34 is only reset when the information of the memory cell 10 is lost due to the fact that no refresh has occurred. In the case that no refresh of the memory cell 10 has been performed, a refresh can be performed again at any time by applying a refresh signal to the refresh input REFRESH, as long as the information in the memory cell 10 is not yet lost, to retain the information not yet lost.

In a further embodiment the circuit shown in FIG. 2 can be used for a plurality of memory cells.

In one embodiment, for example, the memory system may comprise several word lines or common data lines, respectively, each word line being connected to a plurality of memory cells.

An SDRAM chip can, for example, comprise a memory capacity of 256 Mb in four banks each having about 16,000 word lines.

In order to keep the costs for monitoring with such a number of memory cells within reasonable limits, the plurality of memory cells connected to a word line is monitored in one embodiment instead of monitoring each individual memory cell, so that a refresh of memory cells of a word line is only performed when useful information is written to one or more of the memory cells of the word line.

In a further embodiment, a refresh monitoring for memory cells being arranged in respective banks can be performed. Thus the memory cells of a bank are only refreshed when useful information is stored in one of the memory cells.

### List of Reference Numerals

10 memory cell

12 refresh line

14 refreshing means

16 driving means

18 control line

20 control line

22 refresh counter

24 line

26 OR logic element

28 refresh timer

30 line

32 line

34 mono flop

36 AND logic element

38 OR logic element

40 OR logic element

What is claimed is:

1. A memory system comprising:
at least one memory cell having a finite retention time, in which information can be stored;
refreshing means refreshing the memory cell in predetermined time intervals; and
driving means driving the refreshing means in such a way that same only refreshes the memory cell when useful information is stored in the memory cell.

2. The memory system according to claim 1, wherein the driving means drives the refreshing means so as to refresh the memory cell after writing thereto.

3. The memory system according to claim 1, wherein the driving means is formed to drive the refreshing means after receiving a logout signal to stop a refresh.

4. The memory system according to claim 1, wherein the driving means comprises a mono flop and an AND logic element, wherein the mono flop has a hold time which is longer than the retention time of the memory cell, a set input of the mono flop being formed to receive a write signal indicating writing to the memory cell or a refresh signal indicating a refresh of the memory cell, and a reset input of the mono flop being formed to receive the logout signal or a system start signal, and wherein a first input of the AND logic element is connected to an output of the mono flop and a second input of the AND logic element is formed to receive a refresh signal, and further an output of the AND logic being connected to an input of a control for effecting a refresh process.

5. The memory system according to claim 1, wherein the memory system comprises several memory cells connected to a common data line, the driving means driving the refreshing means in such a way that same only refreshes the memory cells of the common data line when useful information is stored in one of the memory cells connected to the common data line.

6. The memory system according to claim 1, wherein the memory system comprises several memory cells being arranged in a bank, the driving means driving the refreshing means in such a way that same only refreshes the memory cells of the bank when useful information is stored in one of the memory cells of the bank.

7. The memory system according to claim 1, wherein the memory cell is a DRAM memory cell or a SDRAM memory cell.

8. A method of refreshing at least one memory cell in which information can be stored, comprising:
determining whether useful information is stored in the memory cell; and
regularly performing refreshes of the memory cell when it has been determined that useful information is stored in the memory cell.

9. The method according to claim 8, wherein the step of refreshing the memory cell is performed responsive to receiving a write signal.

10. The method according to claim 8, further comprising stopping performing regular refreshes of the memory cell responsive to receiving a logout signal.
